(19) United States
(12) Patent Application Publication
(10) Pub. No.: US 2004/0124930 A1
(43) Pub. Date: Jul. 1, 2004

(54) Voltage controlled varactor oscillator with sensitivity spread

(75) Inventors: Thierry Divel, Varces (FR); Julien Mira, Grenoble (FR)

Correspondence Address: FLEIT, KAIN, GIBBONS, GUTMAN, BONGINI, & BIANCO P.L., ONE BOCA COMMERCE CENTER, 551 NORTHWEST 77TH STREET, SUITE 111, BOCA RATON, FL, 33487, US

(73) Assignee: STMICROELECTRONICS S.A., MONTROUGE (FR)

(21) Appl. No.: 10/672,920

(22) Filed: Sep. 26, 2003

(30) Foreign Application Priority Data
Sep. 26, 2002 (FR) 02 11933

(51) Int. Cl. H03L 7/00

(52) U.S. Cl. 331/36 C

(57) ABSTRACT

The invention relates to a voltage controlled oscillator comprising a resonator having an inductive circuit and a capacitive circuit whose oscillations are maintained by an active circuit, the capacitive circuit using varactors whose capacitance is adjusted by a control voltage acting in a differential mode with a biasing voltage. According to the invention, the capacitive circuit comprises several capacitive branches connected in parallel, controlled by a same control voltage, but biased by biasing voltages that are different from one branch to the next. The oscillator of the invention features in particular an oscillation frequency, which is much easier to control, and a considerably reduced phase noise.

### CROSS-REFERENCE TO RELATED APPLICATIONS

This application is based upon and claims priority from prior French Patent Application No. 02 11933 filed on Sep. 26, 2002, the entire disclosure of which is herein incorporated by reference.

### FIELD OF THE INVENTION

The present invention generally relates to the field of relates to electronic circuits and more particularly, the invention relates to a voltage-controlled oscillator with active amplifiers.

### BACKGROUND OF THE INVENTION

An electrical oscillator is a device known to the person skilled in the art for producing an electrical signal at a frequency F defined by a time constant that is specific to the oscillator.

For example, an oscillator constituted by a passive resonant circuit formed by an inductive circuit of inductance L and a capacitive circuit of capacitance C connected in parallel, and by an amplifier, i.e. an active circuit, capable of compensating for electrical losses in the resonant circuit, produces an electrical signal whose frequency F is given by ½π.(L.C)^{1/2}.

To make the resonant frequency F vary, and as allowed for by that formula, it is also known to make either the inductance L of the inductive circuit or the capacitance C of the capacitive circuit variable.

A solution commonly adopted in the latter case consists in using active components, known as varactors, which exhibit a capacitance, which is variable as a function of a control voltage applied thereto, and which thus enable to construct voltage controlled oscillators.

FIG. 1 illustrates that type of oscillator, with a varactor known in the prior art and to which the present invention applies.

If F is the oscillation frequency of such an oscillator, and Vcom is its control voltage, this oscillator can be characterized by a transfer gain G(V) defined by:

G(V)=dF/dVcom

By definition, the transfer gain G(V), which constitutes a fundamental characteristic of the oscillator, is directly linked to the varactor's variation range.

There is a problem in that if this gain it too high, the oscillator becomes sensitive to the slightest variation in the control voltage, and its phase noise itself becomes considerably increased, since it is amplified with a high gain.

Moreover, if this gain is not constant, the oscillator becomes difficult to use in a phase-locked loop, as it would then encounter bandwidth variation problems, which can lead to a considerable increase in integrated noise, a deterioration in the loop's stability and, correlatively, an unacceptable increase in the phase-locked loop's settling time.

Accordingly, what is needed is a voltage-controlled oscillator to overcome the shortcomings and problems with the prior art voltage-controlled oscillators and to provide a voltage-controller oscillator with a reduced transfer gain without a reduction in the range of accessible frequencies.

### SUMMARY OF THE INVENTION

The invention provides a voltage controlled oscillator, comprising an oscillating circuit and an active circuit, the oscillating circuit itself comprising an inductive circuit and a capacitive circuit sharing first and second main terminals to which the active circuit is connected to maintain an oscillatory transfer of electrical energy between the inductive and capacitive circuits at a frequency dependent on the capacitance of the capacitive circuit, this capacitance varying as a function of an adjustable potential difference formed by a difference between a biasing voltage and an adjustable control voltage, the capacitive circuit comprising a first branch of the type of branches which each comprises variable capacitance active elements connected in series between the first and second main terminals and distributed over first and second halves of that branch, these halves being mutually symmetrical relative to a central terminal to which is applied the control voltage, these first and second branch halves of the branch respectively presenting first and second outermost terminals taken to first and second respective voltages, respectively proportional to the voltages of first and second main terminals and shifted by the biasing voltage.

To this end, the oscillator according to the present invention, which besides conforms to the generic definition given in the paragraph above, includes a capacitive circuit comprises a group of branches including, in addition to the first branch, at least a second branch of the same type, in that the different branches of the group are connected in parallel between the first and second main terminals, in that the control voltage is applied to the central terminal of each branch of the group, and in that the outermost terminals of the different branches are biased by biasing voltages which differ from one branch to the other.

In the case where the capacitive circuit comprises at least three branches of the same type, the biasing voltages applied to the outermost terminals of the different branches can take a succession of values, e.g. in a regular fashion.

In a possible embodiment of the oscillator according to the invention, the different branches forming the group comprise different numbers of capacitive elements.

The oscillator of the invention can be implemented notably by using for the variable capacitance capacitive elements MOS (Metal-Oxide Semiconductor) varactors, and by applying each biasing voltage across a resistor.

Finally, the outermost terminals of each branch are preferably connected respectively to the first and second main terminals across first and second respective decoupling capacitors.

### BRIEF DESCRIPTION OF THE DRAWING

The subject matter, which is regarded as the invention, is particularly pointed out and distinctly claimed in the claims at the conclusion of the specification. The foregoing and other features, and advantages of the invention will be apparent from the following detailed description taken in conjunction with the accompanying drawings in which:

FIG. 1 is a circuit diagram showing generically a voltage controlled oscillator operating by a capacitance variation in its capacitive circuit, according to the present invention;

FIG. 2 is a graph showing, in arbitrary units, the values Y taken by the capacitor and the sensitivity of a varactor as a function of the difference between its biasing voltage and its control voltage, according to the present invention;

FIG. 3 is a circuit diagram showing a known type of capacitive circuit of FIG. 1 for implementing a voltage controlled oscillator in a differential mode, according to the present invention;

FIG. 4 is a graph showing, in arbitrary units, the capacitance Cb exhibited by the circuit of FIG. 3 in the case where that circuit comprises just two varactors, and the capacitance CT exhibited by the capacitive circuit CAPA of FIG. 1 in the case where that circuit is formed by a circuit in conformity with that of FIG. 3 and using eight varactors, according to the present invention;

FIG. 5 is a circuit diagram showing a capacitive circuit for implementing a voltage controlled oscillator in a differential mode, according to the present invention; and

FIG. 6 is a graph showing, in arbitrary units, the capacitance Cb exhibited by each branch of a capacitive circuit CAPA having four branches and eight varactors having a structure such as illustrated in FIG. 5, and the total capacitance CT exhibited by that same capacitive circuit CAPA having four branches and eight varactors, according to the present invention.

### DESCRIPTION OF THE PREFERRED EMBODIMENTS

It should be understood that these embodiments are only examples of the many advantageous uses of the innovative teachings herein. In general, statements made in the specification of the present application do not necessarily limit any of the various claimed inventions. Moreover, some statements may apply to some inventive features but not to others. In general, unless otherwise indicated, singular elements may be in the plural and vice versa with no loss of generality.

As stated above, the invention relates to a voltage controlled oscillator formed essentially of an oscillating circuit OSCILL and an active circuit ACT.

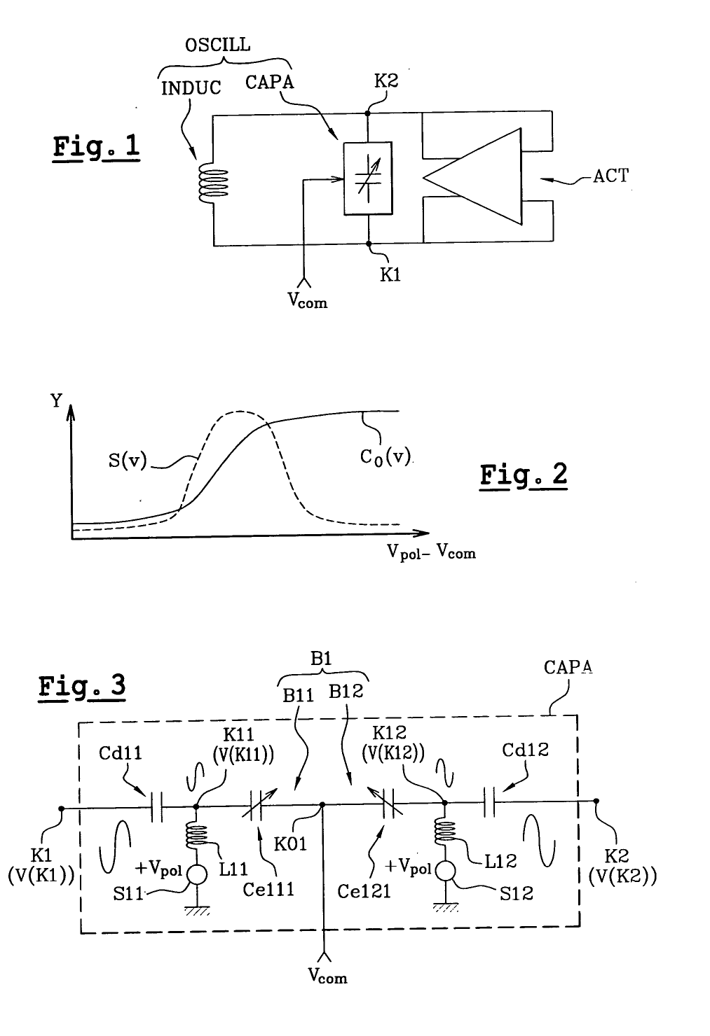

The oscillating circuit OSCILL itself comprises an inductive circuit INDUC and a capacitive circuit CAPA connected in parallel with respect to each other between two main terminals K1 and K2 as shown in FIG. 1.

The active circuit ACT, which is connected to the terminals K1 and K2, has the function of bringing the electrical energy required for maintaining an oscillatory transfer of electrical energy between the inductive circuit INDUC and capacitive circuit CAPA, that transfer of energy exhibiting an oscillation frequency F which varies as a function of the capacitance CT of the capacitive circuit CAPA.

FIG. 3 illustrates a known capacitive circuit CAPA of FIG. 1, this circuit being formed by a single branch B1 comprising capacitive elements having a variable capacitance Co(V), such as varactors Ce111 and Ce121 connected in series between the main terminals K1 and K2.

These varactors, which are in even number, are distributed over two halves B11 and B12 of branch B1, these halves being mutually symmetrical with respect to a central terminal K01 on which is applied a control voltage Vcom.

Branch B1 possesses, at its respective halves B11 and B12, outermost terminals K11 and K12 respectively connected to the main terminals K1 and K2 across decoupling capacitors, respectively Cd11 and Cd12.

The decoupling capacitors Cd11 and Cd12 form, with the varactors Ce111 and Ce121, and between the central terminal K01 and the outermost terminals K11 and K12, respective capacitive dividers by virtue of which the voltages VK11 and VK12 of the outermost terminals K11 and K12 have amplitudes that are respectively linked to those of the voltages VK1 and VK2 of the main terminals K1 and K2, and reduced by proportionality coefficients which are identical, although variable as a function of the capacitance of the varactors Ce111 and Ce121.

The halves B11 and B12 of branch B1 further comprise respective voltage sources S11 and S12, which apply a biasing voltage Vpol to the respective outermost terminals K11 and K12 of that branch via corresponding biasing inductances L11 and L12.

The voltages VK11 and VK12 of the outermost terminals K11 and K12 are thus respectively proportional to the voltages VK1 and VK2 of the main terminals, and shifted relative to the latter by the value of the biasing voltage Vpol.

Under these conditions, the total capacitance CT of branch B1 varies as a function of the difference V=Vpol-Vcom between the biasing voltage Vpol and the adjustable control voltage Vcom.

FIG. 2 shows the evolution, as a function of that difference V=Vpol−Vcom, of the capacitance Co(V) and of the sensitivity S of a varactor, the sensitivity S being defined as a function of the potential difference V by:

S(V)=d(C)/d(V).

In fact, although FIG. 3 shows just two varactors, it is in practice often useful to connect several varactors in parallel on each half of branch B1 to be able to cover the entire desired adjustable frequency range.

The greater is this frequency range, the more the number of varactors used is thus high.

Some technologies do not make it possible to use varactors having steep operating characteristics, and thus a high and strongly nonlinear sensitivity, leading to a high phase noise in the oscillator.

Now, the more the number of unitary oscillators is high, the more the total sensitivity of the capacitive circuit CAPA is high.

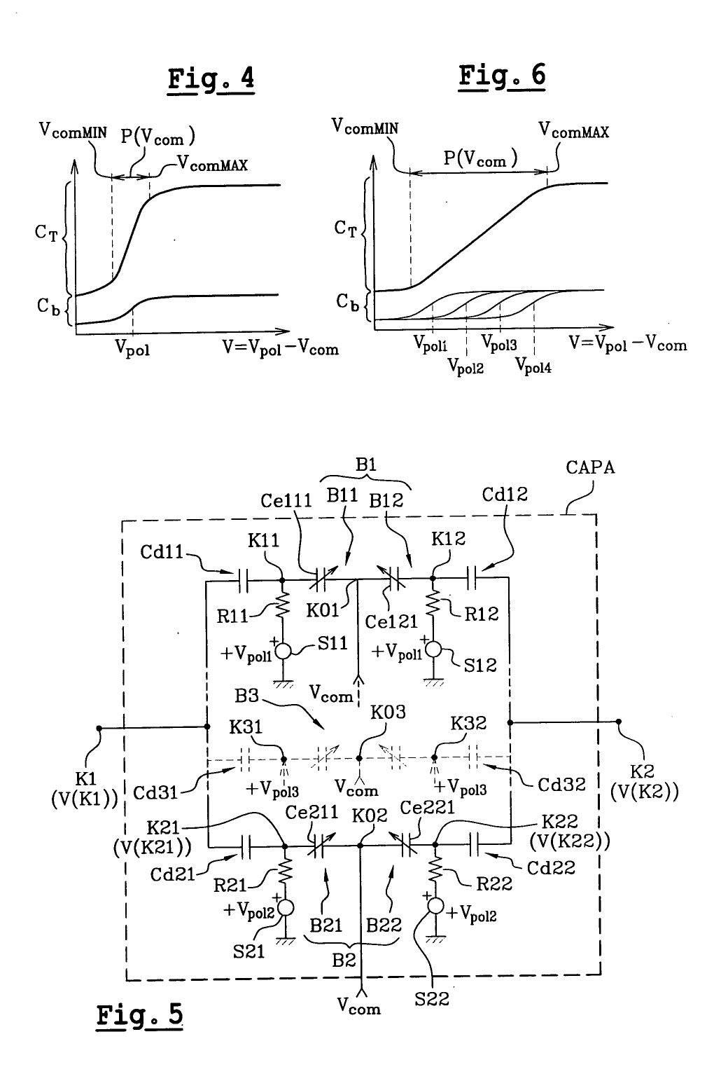

This relationship is illustrated by FIG. 4, in which Cb is the capacitance of the circuit of FIG. 3 in the case where this circuit comprises just two varactors, and for which CT is the capacitance of the capacitive circuit CAPA of FIG. 1, in the case where that circuit has the structure of that of FIG. 3 but using eight varactors.

As this FIG. shows, the range P(Vcom) over which the control voltage Vcom can be chosen, between its minimum value VcomMIN and its maximum value VcomMAX, is thus very narrow.

Since the control frequency is represented by the potential difference V=Vpol−Vcom, the stability of that difference is all the greater as the total sensitivity of the capacitive circuit CAPA is high.

Indeed, in such a case, a variation of a few millivolts in the control voltage can cause the frequency F to vary by several Megahertz.

Now, it is precisely very difficult to produce low noise integrated reference voltages, whether it be for the biasing voltage or the control voltage.

The solution proposed by the invention consists, schematically, in distributing the sensitivity of the varactors of the group over a wider control voltage range.

To this end, the capacitive circuit CAPA, instead of comprising just one branch B1, in fact comprises a group of several branches of the same type, such as B1, B2 and B3, which are connected in parallel with respect to each other between the main terminals K1 and K2.

Moreover, the control voltage Vcom is applied to the central terminal, such as K01, K02 and K03 of each of the branches B1, B2 and B3 of the group, while the outermost branches such as K11, K12, K21, K22, K31 and K32 of these different branches are biased by biasing voltages, such as Vpol1, Vpol2 and Vpol3, which differ from one branch to the next.

The varactors of each branch thus function, for a same control voltage Vcom, in a zone of their characteristic Co(V) which is specific to that branch, the different zones exploited being shifted with respect to each other over the different branches.

This operating mode and its effects are illustrated by FIG. 6, in which Cb is the capacitance of each branch of a capacitive circuit CAPA formed of four branches and eight varactors having a structure such as illustrated in FIG. 5, i.e. in accordance with the teachings of the invention, and in which CT is the total capacitance exhibited by that same capacitive circuit CAPA having four branches and eight varactors.

As this FIG. shows, the range P(Vcom) over which the control voltage Vcom can be chosen between its minimum value VcomMIN and its maximum value VcomMAX is then much broader than in the case of the prior art, illustrated in FIG. 4.

In the case where the capacitive circuit CAPA comprises three branches or more of the same type, such as branches B1, B2 and B3, the biasing voltages Vpol1, Vpol2, Vpol3 applied to the outermost terminals such as K11, K12, K21, K31 and K32 of those different branches take e.g. a succession of values in a regular fashion.

In this case, the equality Vpol3−Vpol2=Vpol2−Vpol1 is then verified in the case of three branches, and the equalities Vpol4−Vpol3=Vpol3−Vpol2=Vpol2−Vpol1 are verified in the case of four branches, as shown in FIG. 6.

Nevertheless, it is equally possible to make the intervals between successive pairs of biasing voltages different from each other to allow for an adjustment of the sensitivity S(V).

Moreover, it is possible to provide the capacitive circuit CAPA with a structure in which the different branches such as B1 to B3 comprise different numbers of varactors, where each half-branch can comprise several varactors in parallel.

The invention is particularly well suited and effective in the case where the varactors used are of the Metal-Oxide-Semiconductor (MOS) type.

The invention offers numerous advantages.

Firstly, since the range P(Vcom) of the control voltage useable for controlling the frequency is greater, and the oscillator's transfer gain is correlatively smaller, this oscillator can be feedback controlled by a phase-locked loop.

The bandwidth problems are greatly attenuated, the integrated noise is significantly reduced, and the settling time is substantially reduced.

The oscillator's transfer gain being constant and reduced, the oscillator's phase noise is less sensitive to the noise generated by the biasing electronics.

It is thereby no longer necessary to use biasing and decoupling inductors, it being possible to apply each of the biasing voltages such as Vpol1, Vpol2 and Vpol3 across a simple resistor such as R11, R12, R21 and R22.

Insofar as the biasing inductors used in the prior art were of medium quality considering their cost, and thus themselves sources of noise, while relatively cumbersome, the obviation of these inductances brings at the same time a space saving, a non-negligible cost saving, and an additional reduction in noise.

By virtue of the invention, the oscillator's phase noise is constant throughout the frequency band covered, given that the contribution of the bias to the noise is constant, and no longer strongly amplified around the biasing voltage.

Although a specific embodiment of the invention has been disclosed, it will be understood by those having skill in the art that changes can be made to this specific embodiment without departing from the spirit and scope of the invention. The scope of the invention is not to be restricted, therefore, to the specific embodiment, and it is intended that the appended claims cover any and all such applications, modifications, and embodiments within the scope of the present invention.

What is claimed is:

1. A voltage-controlled oscillator, comprising:
an oscillating circuit and an active circuit, the oscillating circuit including an inductive circuit and a capacitive circuit sharing a first main terminal with a first main terminal voltage and a second main terminal with a second main terminal voltage to which the active circuit is connected to maintain an oscillatory transfer of electrical energy between the inductive circuit and the capacitive circuit at a frequency dependent on the capacitance of the capacitive circuit, the capacitance varying as a function of an adjustable potential difference formed by a difference between a biasing voltage and an adjustable control voltage, the capacitive circuit includes:
one or more circuit branches, where each circuit branch comprises a first half and a second half, the first half and the second half each comprises at least one capacitive element of variable capacitance connected in series between the first main terminal and the second main terminal and distributed over the first half and the second half so that each of the first half and the second half is mutually symmetrical with respect to a central terminal on which the adjustable control voltage is applied;
wherein the first half includes an outer most terminal with a first voltage proportional to the first main terminal voltage shifted by the biasing voltage and;
wherein the second half includes an outer most terminal with a second voltage proportional to the second main terminal voltage shifted by the biasing voltage.

2. The voltage control oscillator of claim 1, wherein the one or more circuit branches includes at least one additional circuit branch connected in parallel between the first main terminal and the second main terminal, so that the control voltage is applied to the central terminal of each circuit branch, and the outermost terminal of each circuit branch are biased by different biasing voltages.

3. The voltage-controlled oscillator according to claim 1, wherein the one or more circuit branches includes least three branches.

4. The voltage-controlled oscillator according to claim 1, wherein each biasing voltage in each of the one or more circuit branches is configured to be a voltage value which taken together as a group of biasing voltages forms a succession of biasing voltage values.

5. The voltage-controlled oscillator according to claim 1, wherein each of the one or more circuit branches includes a different number of capacitive elements.

6. The voltage-controlled oscillator according to claim 1, wherein at least one of the capacitive elements is a MOS (Metal-Oxide-Semiconductor) type varactors.

7. The voltage-controlled oscillator according to claim 5, wherein at least one of the capacitive elements is a MOS (Metal-Oxide-Semiconductor) type varactors.

8. The voltage-controlled oscillator according to claim 2, wherein each biasing voltage in each of the one or more circuit branches is applied via a resistor.

9. The voltage-controlled oscillator according to claim 7, wherein each biasing voltage in each of the one or more circuit branches is applied via a resistor.

10. The voltage-controlled oscillator according to claim 1, wherein at least one outer most terminal of at least one of the one or more circuit branches includes at least one decoupling capacitor.

11. The voltage-controlled oscillator according to claim 9, wherein at least one outer most terminal of at least one of the one or more circuit branches includes at least one decoupling capacitor.

12. A voltage-controlled oscillator, with an active circuit and an oscillating circuit including a capacitive circuit with a capacitance varying as a function of an adjustable potential difference formed by a difference between a biasing voltage and an adjustable control voltage, the capacitive circuit including:
at least one circuit branch, where each circuit branch comprises a first half and a second half, the first half and the second half each comprises at least one capacitive element of variable capacitance connected in series between a first main terminal with a first main terminal voltage and a second main terminal with a second main terminal voltage and distributed over the two halves so that each of the halves includes an outer most terminal with a voltage which is proportional to one of:
the first main terminal voltage shifted by a biasing voltage and
the second main terminal voltage shifted by a biasing voltage.

13. The voltage control oscillator of claim 12, wherein the circuit branch includes at least one additional circuit branch connected in parallel between the first main terminal and the second main terminal, so that the control voltage is applied to the central terminal of each circuit branch, and the outermost terminal of each circuit branch are biased by different biasing voltages.

14. The voltage-controlled oscillator according to claim 12, wherein at least one circuit branch includes least three branches.

15. The voltage-controlled oscillator according to claim 12, wherein each biasing voltage in each circuit branch is configured to be a voltage value which taken together as a group of biasing voltages forms a succession of biasing voltage values.

16. The voltage-controlled oscillator according to claim 12, wherein one circuit branch includes a different number of capacitive elements as compared with another circuit branch.

17. The voltage-controlled oscillator according to claim 12, wherein at least one of the capacitive elements is a MOS (Metal-Oxide-Semiconductor) type varactors.

18. The voltage-controlled oscillator according to claim 17, wherein at least one of the capacitive elements is a MOS (Metal-Oxide-Semiconductor) type varactors.

19. The voltage-controlled oscillator according to claim 12, wherein at least one of the biasing voltage in the circuit branch is applied via a resistor.

20. The voltage-controlled oscillator according to claim 18, wherein each biasing voltage in each circuit branch is applied via a resistor.

21. The voltage-controlled oscillator according to claim 12, wherein at least one outer most terminal of at least one circuit branch includes at least one decoupling capacitor.

22. The voltage-controlled oscillator according to claim 18, wherein at least one outer most terminal of at least one circuit branch includes at least one decoupling capacitor.
